(19) United States
(12) Patent Application Publication
(10) Pub. No.: US 2026/0042663 A1
(43) Pub. Date: Feb. 12, 2026

(54) METHOD FOR MAKING A HOLLOW STRUCTURE, AND MICROMECHANICAL SENSOR HAVING SUCH A HOLLOW STRUCTURE

(71) Applicant: Robert Bosch GmbH, Stuttgart (DE)

(72) Inventors: Heribert Weber, Nuertingen (DE); Peter Schmollngruber, Aidlingen (DE)

(21) Appl. No.: 19/286,452

(22) Filed: Jul. 31, 2025

(30) Foreign Application Priority Data
Aug. 7, 2024 (DE) 10 2024 207 513.2

(51) Int. Cl. B81C 1/00; B81B 3/00

(52) U.S. Cl. CPC B81C 1/00515; B81B 3/0021; B81B 2201/0264; B81C 2201/0132; B81C 2201/016

(57) ABSTRACT

A method for making a hollow structure in a substrate. The method includes creating a lattice structure with at least two mutually spaced trench structures, creating a cavity structure below the lattice structure with respect to a normal direction by forming a buried, contiguous cavity that spans at least the area of the two trench structures. A micromechanical sensor is also described.

### CROSS REFERENCE

The present application claims the benefit under 35 U.S. C. § 119 of Germany Patent Application No. 10 2024 207 513.2 filed on Aug. 7, 2024, which is expressly incorporated herein by reference in its entirety.

### FIELD

The present invention relates to a method for making a hollow structure. Furthermore, the present invention relates to a micromechanical sensor having such a hollow structure.

### BACKGROUND INFORMATION

German Patent Application No. DE 10 2004 043 356 A1 describes a method for making a hollow structure in a substrate material. First, a structured etching mask is applied to the substrate material to create holes in a predefined pattern. An anisotropic etching process is then carried out, consisting of alternating cycles of etching and passivation. This leads to the formation of trench holes with high aspect ratios and, depending on the method, side walls that are ridged to a greater or lesser extent. During the formation of the trench holes, a passivation layer is applied to the side walls after each etching step and removed again at the bottom of the recess that forms, in order preferably to allow material removal in the depth direction. Finally, a longer isotropic etching step is carried out, which, starting from the bottom of the created hole structures, creates a contiguous cavity below the created hole structures in the substrate material.

It is also described how to form a buried lattice by applying the method iteratively. After the access holes and a cavity have been created, the trench etching process that formed the access holes is continued. Further depressions are thereby made in the substrate material starting from the bottom of the cavity below the access holes. If the last etching step of the trench etching process is carried out for a longer time to produce the further depressions, a further cavity is formed below the formed buried lattice.

### SUMMARY

According to the present invention, a method for making a hollow structure in a substrate is provided. According to an example embodiment of the present invention, the method includes creating a lattice structure with at least two mutually spaced trench structures; creating a cavity structure below the lattice structure with respect to a normal direction by forming a buried, contiguous cavity that spans at least the area of the two trench structures; the cavity structure is extended below and directly adjacent to the cavity with respect to the normal direction in the substrate by forming a buried, contiguous further cavity that spans at least the area of the two trench structures by carrying out a cavity formation method, comprising applying a passivation layer at least to the surfaces of the cavity; removing the passivation layer exclusively on the bottom surface of the cavity with respect to the normal direction; and an etching process for removing the substrate material of the substrate below the bottom surface by supplying an etching substance through the lattice structure.

This allows the dimensions of the cavity structure to be selected flexibly. For example, deep cavity structures with respect to the normal direction can be produced in the substrate with smaller surface areas in comparison with the depth. A depth of the cavity structure can be independent of a thickness of the layer structure having the lattice structure.

According to an example embodiment of the present invention, the substrate material can be composed of a semiconductor, in particular mainly or entirely of silicon. The substrate material can be composed, in particular mainly or exclusively, of monocrystalline and/or polycrystalline silicon. The substrate material can be doped or undoped.

The passivation layer can be made of silicon nitride, silicon dioxide and/or a polymer. The passivation layer can be applied in a plasma-forming system using a polymer-forming gas and/or gas mixture, in particular using a gas and/or gas mixture comprising a carbon-containing gas such as C4F8, CH2F2, CHF3 or CF4 and/or by LPCVD deposition and/or created by thermal oxidation.

According to an example embodiment of the present invention, the etching process can comprise wet etching and/or dry etching, in particular plasma etching, for example by means of a fluorine-containing gas, for example with SF6, CF4, NF3.

According to an example embodiment of the present invention, the creation of the lattice structure can comprise a trench process. The lattice structure can comprise one-dimensional or two-dimensional distributed trench structures. The trench structures can also be called trenches. The creation of the lattice structure can comprise the application of an etching mask, for example made of photoresist and/or silicon dioxide.

The normal direction refers to a direction normal to the surface of the lattice structure and is to be understood as bidirectional.

The lattice structure can be contiguous in area with a further lattice structure or spaced apart from it.

The layer structure can be constructed from a single layer or multiple layers arranged one above the other. The layer or layers can be structured. The layer or layers can consist of or be constructed from the same material and/or a different material. The layer or layers can be doped or undoped.

According to an example embodiment of the present invention, after the creation of the cavity structure, at least the substrate can be exposed to a high temperature. This allows the side walls of the cavity structure to be smoothed and/or corners within the cavity structure to be rounded, in particular by diffusion of silicon atoms.

After the creation of the cavity structure, a surface treatment method, for example a chemical-mechanical polishing process (CMP process), can be carried out, in particular to achieve the highest possible flatness or planarity and/or low roughness of the surface.

The cavity structure can have at least one layer applied to the cavity surface at least in some portions, in particular completely. The at least one layer can be constructed at least partially from silicon, for example from polycrystalline and/or monocrystalline silicon. The at least one layer can be at least partially doped or undoped. The doping of at least partial regions of the at least one layer can be different and/or identical to the doping of the substrate.

After the creation of the cavity structure, all passivation layers can be removed. Also, the passivation layers can only be partially removed.

According to an example embodiment of the present invention, a further substrate and/or a further layer structure can be arranged at least in some regions on the substrate or on a layer structure arranged on the substrate, spaced apart from the substrate and/or the layer structure. An intermediate space can be formed between the substrate and/or the layer structure and the further substrate and/or the further layer structure. The cavity structure can connect the intermediate space in a fluid-transmitting manner with a surface of the substrate facing away from the intermediate space. This allows, for example, pressure access between the surface and the intermediate region to be implemented through the cavity structure. As a result, for example, a pressure sensor arranged in or adjacent to the intermediate space can measure an ambient pressure and/or a change in ambient pressure. The cavity structure can form a fluid passage for supplying the intermediate space with a fluid.

In a preferred embodiment of the present invention, it is advantageous when the cavity formation method is applied at least once more starting from the further cavity. The cavity formation method can form further cavities below the further cavity with respect to the normal direction through repeated application. By repeatedly carrying out the cavity formation method, vertical or inclined side walls can be created in the cavity structure and/or any cross-sectional contours can be created in the cavity structure with respect to a plane having the normal direction.

The etching processes of at least two cavity formation methods can take the same or different lengths of time. The dimensions of the further cavities can be influenced by the duration of the particular etching process and depending on the etching conditions.

In a preferred embodiment of the present invention, it is advantageous when at least two of the passivation layers that are applied during the creation of the cavity and the formation of the further cavity and/or at least one additional further cavity when the cavity formation method is carried out again are constructed or formed from different materials from one another. For example, one passivation layer can consist of silicon dioxide, while the passivation layer in the or in one of the subsequent cavity formation methods can be constructed or formed from a polymer, for example. Also, when the cavity formation method is carried out again, the applied passivation layer can be applied by a method different from the method used to create the passivation layer in the or in one of the previous cavity formation methods.

In a preferred embodiment of the present invention, it is advantageous when the cavity and/or the further cavity has a surface area spanning at least the entire lattice structure with respect to a plane having the normal direction as the normal. The cavity and the further cavity can have the same or a different surface area. A maximum dimension of the cavity structure, i.e., a width or length, in a direction perpendicular to the normal direction can be larger than the corresponding dimension, i.e., a width or length, of the lattice structure.

In a preferred embodiment of the present invention, it is advantageous when the etching process of the cavity formation method comprises isotropic etching for the removal of the substrate material by the etching substance. The etching process of the cavity formation method can comprise exclusively isotropic etching. Anisotropic etching can be omitted from the etching process of the cavity formation method.

In a preferred embodiment of the present invention, after the cavity formation method has been carried out, the lattice structure is formed in a layer structure that spans the cavity structure in a self-supporting manner. The trench structures can extend through the entire thickness of the layer structure. The trench structures can connect the two opposing surfaces of the layer structure to one another in a fluid-transmitting manner.

A thickness of the layer structure can be independent of the depth of the ultimately created cavity structure along the normal direction and/or the length and/or the width of the ultimately created cavity structure in a direction perpendicular thereto.

In a preferred embodiment of the present invention, after the cavity has been formed using the cavity formation method, the passivation layer is also applied to the underside of the side of the lattice structure facing the cavity. The underside refers to the normal direction. The underside of the lattice structure can thereby be protected from an etching attack during the formation of the cavity structure, and its thickness can be selected independently of the depth of the created cavity structure.

In an advantageous embodiment of the present invention, a depth of the cavity structure after creation of the cavity structure along the normal direction is greater than at least a width and/or length in a direction perpendicular thereto. The depth of the cavity structure can preferably be manufactured independently of the width and/or length. A ratio of the depth to the width or length of the cavity structure can be greater than 1.5, greater than 2, greater than 3, greater than 5 or greater than 10.

In a specific embodiment of the present invention, it is advantageous when, after the creation of the cavity structure, at least one channel connected to the cavity structure is formed. The channel can extend to a surface of the substrate and/or a surface of a layer structure on the substrate. The channel can be open or closed to the surface. The channel can be closed by another layer structure. The channel can be closed by at least one closure material. The channel can be closed by melting, for example with a laser and/or by depositing at least one layer of material. The closure material can seal off the cavity structure from an environment. The closure material on the channel can seal off the described intermediate space from an environment.

A defined fluid pressure in the cavity structure which is preferably as low as possible and/or a defined gas atmosphere within the cavity structure can be created via the channel.

Before the channel is made, the surface can be removed using a grinding and/or polishing process. This allows the thickness of the surface material to be adjusted.

A depression can be provided on the surface in the region of the channel, whereby the channel is arranged at a distance from the surrounding surface. This allows the closure material in the region of the channel to be protected, for example, from mechanical damage during subsequent process steps on the substrate during which the surface of the substrate can, for example, come into full contact with a support surface or a so-called chuck.

A preferred embodiment of the present invention is advantageous in which, after the creation of the cavity structure, a top layer, which covers at least the lattice structure, is applied, in particular deposited and/or grown. The top layer can be constructed from the same material as the substrate material or from a different material. The top layer can be constructed from a monocrystalline or polycrystalline semiconductor material, in particular silicon. The top layer can be applied by an epitaxial method and/or an LPCVD deposition method and/or a PECVD deposition method and/or a sputtering method and/or a vapor deposition method. The top layer can be the layer exposed to an environment. The top layer can be at least partially doped and/or undoped. The top layer can at least partially have doping that is the same as and/or different from the substrate. The top layer can belong to a layer structure above the substrate material. The layer structure can contain or accommodate ASIC and/or MEMS components and form a layer system.

The high temperature exposure of the substrate can be carried out before or after the application of the top layer.

A subsequent treatment step, in particular the chemical-mechanical polishing process, can be applied to the surface of the top layer. ASIC and/or MEMS components can then be created on or in such a prepared surface using standard semiconductor technology methods and used to manufacture microelectronic circuits and/or sensors. This allows another layer system to be built up on the top layer.

In a preferred embodiment of the present invention, it is advantageous when the lattice structure is closed after the creation of the cavity structure. The cavity structure can thereby be designed as a hollow space that is closed off from the lattice structure. The cavity structure can be completely sealed against gaseous media. The cavity structure can be connected to an environment exclusively via the at least one channel. The lattice structure can be closed in a gas-tight manner with the material of the top layer.

According to the present invention, a micromechanical sensor is also provided. The micromechanical sensor can be a gas sensor, a pressure sensor, a microphone, a gyroscope or an acceleration sensor.

The cavity structure can be an extension of the volume of a hollow space of the micromechanical sensor. The layer system can have at least one sensing region for converting a physical measurement variable, for example an ambient variable such as an ambient pressure or an acting variable such as an acceleration, into an electrical, magnetic and/or optical measurement variable. The cavity structure can extend such that it at least partially overlaps the sensing region in area.

Further advantages and advantageous embodiments of the present invention can be found in the description herein and in the figures.

### BRIEF DESCRIPTION OF THE DRAWINGS

The present invention is described in detail below with reference to the figures.

FIGS. 1A-1C show a method for producing a hollow structure in a specific example embodiment of the present invention.

FIG. 2 shows further method steps of the method of FIGS. 1A-1C.

FIGS. 3 to 13 each show a cross section of a layer structure of a substrate after application of a method in a further specific example embodiment of the present invention.

FIG. 14 to 18 each show a cross section of a micromechanical sensor in a specific example embodiment of the present invention.

### DETAILED DESCRIPTION OF EXAMPLE EMBODIMENTS

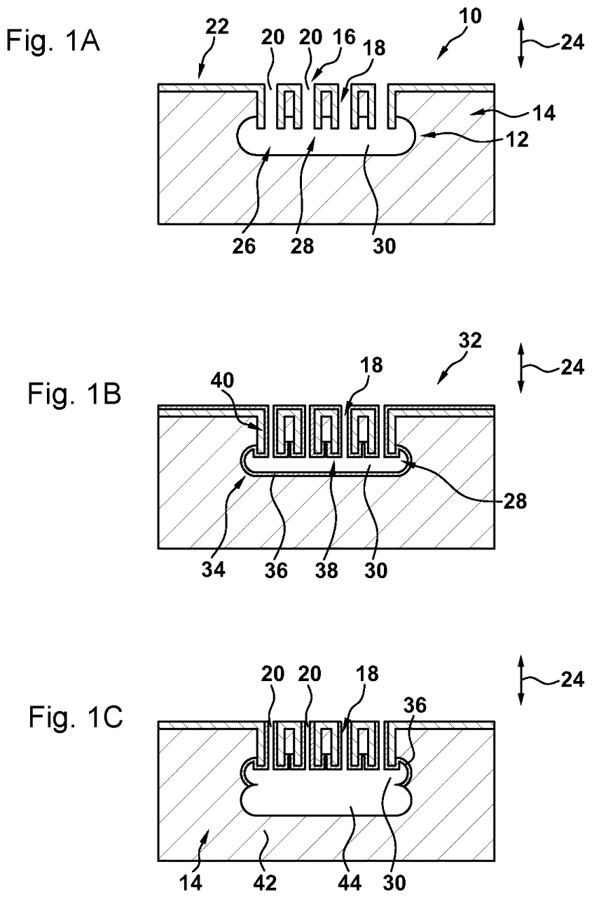

FIGS. 1A-1C show a method for producing a hollow structure in a specific embodiment of the present invention. The method is explained here using a cross section of a substrate as an example. The method 10 for making a hollow structure 12 in a substrate 14 comprises, as shown in FIG. 1A, first creating 16 a lattice structure 18 with multiple mutually spaced trench structures 20. The trench structures 20 can be produced by a trench etching process. In the process, for example, recesses, which are predefined by an etching mask, for example made of photoresist and/or silicon dioxide, are created on the surface 22 of the substrate 14, in particular by anisotropic etching. The recesses in the etching mask are then deepened by single or repeated etching and passivation along a normal direction 24, which is to be understood here as a bidirectional reference.

A passivation layer is then applied over the entire area. The passivation layer is also deposited on the side walls of the trench structures 18 and protects them from an etching attack in a subsequent etching process. After the passivation layer at the bottom of the trench structures 20 is removed, a cavity structure 28, which is not yet fully formed here, is created 26 in the substrate 14 below the lattice structure 18 with respect to the normal direction 24, that is to say from the bottom of the trench structures 20, by forming a buried, contiguous cavity 30 that spans the area of the multiple trench structures 20. The cavity 30 can be formed by applying the etching process producing the trench structures 20 for a longer period of time. As a result, the recesses of the trench structures 20 merge and form the cavity 30 directly below the trench structures 20 of the lattice structure 18.

The cavity structure 28 is extended by carrying out a cavity formation method 32 below the lattice structure 18 with respect to the normal direction 24 in the substrate 14. The cavity formation method 32 comprises, as shown in FIG. 1B, applying 34 a passivation layer 36 on all freely accessible surfaces. After the cavity 30 has been formed by the preceding etching process, the passivation layer 36 is also applied to the underside 38 of the layer structure 40 having the lattice structure 18 and spanning the cavity 30 in a self-supporting manner.

Subsequently, as shown in FIG. 1C, the passivation layer 36 is removed exclusively on the bottom surface with respect to the normal direction 24, and an etching process is carried out to remove the substrate material 42 of the substrate 14 below the bottom surface by supplying a preferably gaseous etching substance through the lattice structure 18. This creates a further, buried, contiguous cavity 44 that spans the area of the multiple trench structures 20 directly below the previous cavity 30. The etching process in particular comprises isotropic etching.

The cavity 30 and the further cavity 44 have a surface area spanning at least the entire lattice structure 18 with respect to a plane having the normal direction 24 as the normal.

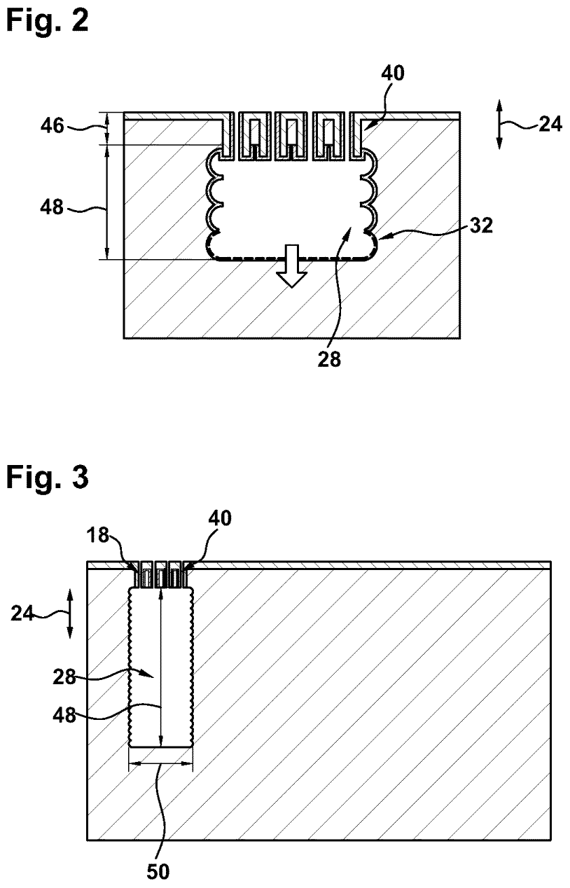

FIG. 2 shows further method steps of the method of FIGS. 1A-1C. The cavity formation method 32 can be applied multiple times in succession to extend the cavity structure 28 downward into the substrate 14. As a result, the cavity structure 28 can be formed flexibly and independently of the thickness 46 of the layer structure 40. For example, deep cavity structures 28 with respect to the normal direction 24 can be produced with small surface areas in comparison with the depth 48.

FIG. 3 to 13 each show a cross section of a layer structure of a substrate after application of a method in a further specific embodiment of the present invention. In FIG. 3, the cavity structure 28 below the lattice structure 18 is created by repeatedly applying the cavity formation method. Above the cavity structure 28, the self-supporting layer structure 40 having the lattice structure 18 is formed. A depth 48 of the cavity structure 28 after creation of the cavity structure 28 along the normal direction 24 is greater than at least a width 50 in a direction perpendicular thereto.

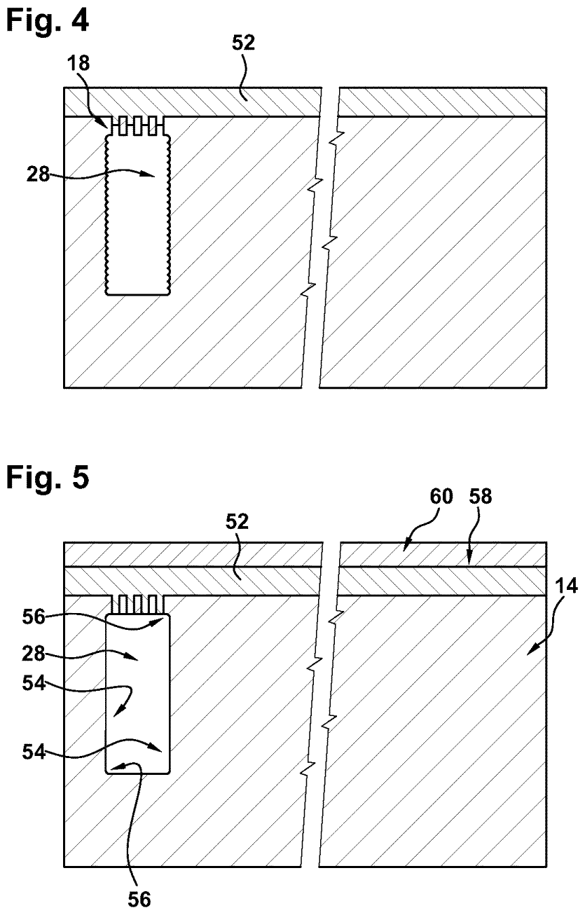

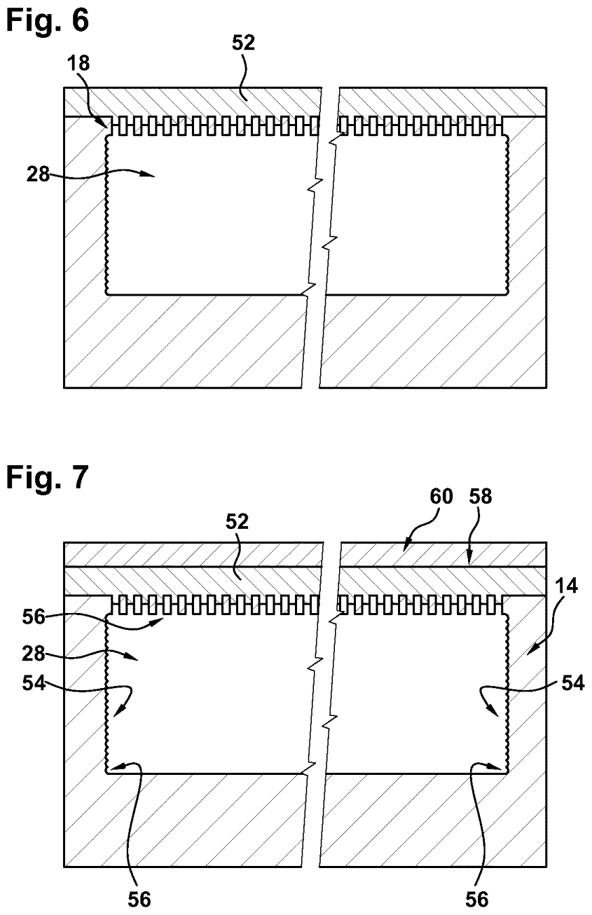

In FIG. 4 and FIG. 6, the etching mask and all passivation layers have been removed after the cavity structure 28 has been created. Furthermore, after the creation of the cavity structure 28, at least one top layer 52 covering at least the lattice structure 18 was applied, in particular grown, and the lattice structure 18 was closed with the material of the top layer 52. The top layer 52 can be formed, for example, by an epitaxial method and/or an LPCVD deposition method. The top layer 52 can consist of or be constructed from monocrystalline and/or polycrystalline silicon. The top layer 52 can be at least partially doped and/or undoped.

As shown in FIGS. 5 and 7, after the creation of the cavity structure 28, the substrate 14 was exposed to high temperatures. As a result, the side walls 54 of the cavity structure 28 can be smoothed and/or corners 56 within the cavity structure 28 can be rounded, in particular by diffusion of silicon atoms on silicon surfaces. The high temperature exposure of the substrate 14 can take place before and/or after the closure of the lattice structure 18 by the at least one top layer 52. After the lattice structure 18 has been closed by the at least one top layer 52, a surface treatment method, for example a chemical-mechanical polishing process (CMP process), can also be carried out, in particular in order to achieve the highest possible evenness or planarity of the surface 58. A further layer structure 60 can be applied to the surface 58 of the top layer 52 prepared in this way, for example using standard semiconductor technology methods used to manufacture ASIC and/or MEMS components and to manufacture microelectronic circuits and/or sensors.

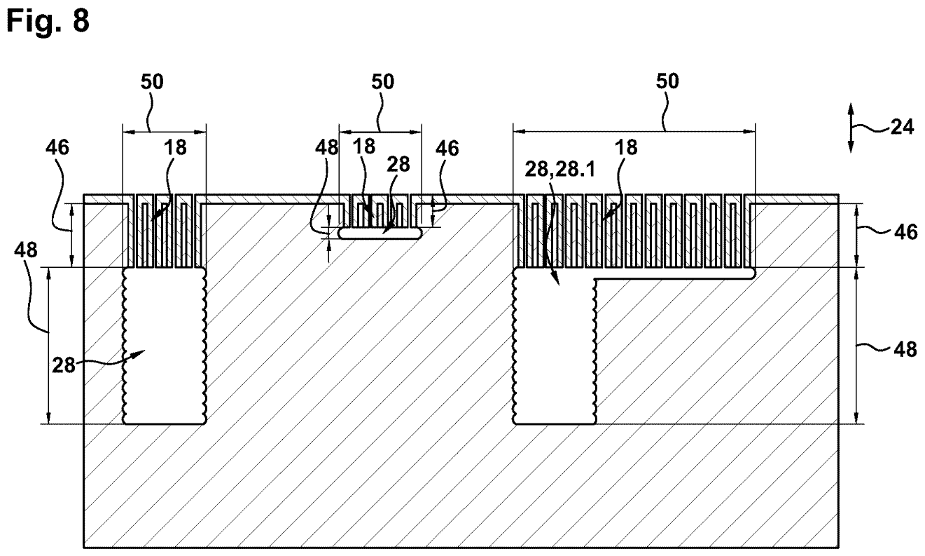

FIG. 8 shows a layer structure of the substrate which, by combining or sequentially applying multiple etching masks, has cavity structures 28 each with a different depth 48 and width 50 and in which the thickness 46 of the particular lattice structure 18 can also be adjusted as desired. As can be seen in the right-hand cavity structure 28.1, by combining or sequentially applying multiple etching masks, a cavity structure can be produced that can have regions formed to different depths with respect to the normal direction 24 and in which the regions formed to different depths can have any desired surface areas with respect to a plane having the normal direction 24.

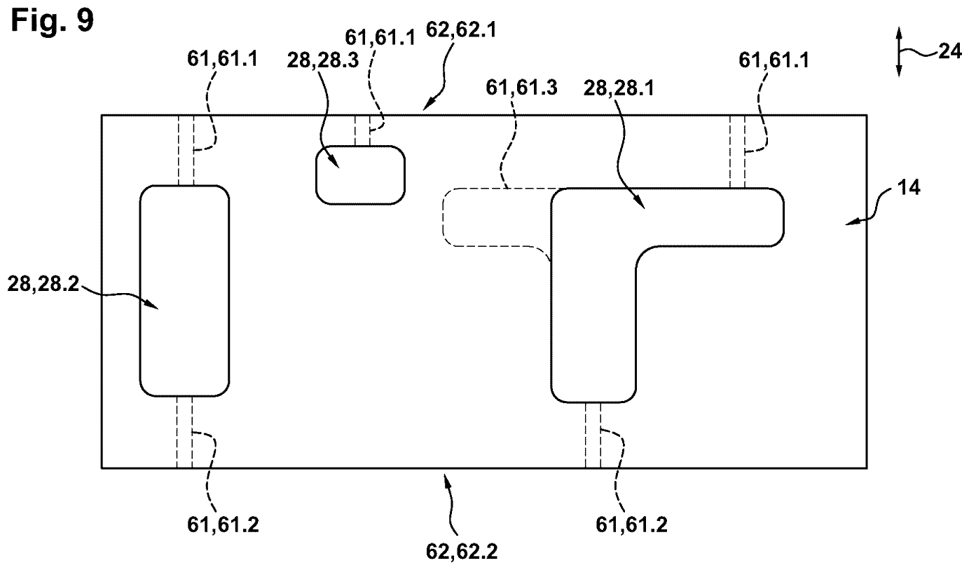

FIG. 9 shows a layer structure of the substrate with multiple cavity structures 28 that are closed by closing the lattice structures. The cavity structures 28 can be connected to channels 61, which connect the cavity structures 28 to the surfaces 62 and allow fluid exchange between an ambient medium and the cavity structures 28 or which run only within the substrate 14. As can be seen in the left cavity structure 28.2 and the right cavity structure 28.1, a channel 61.1 can lead from the surface 62.1 into the particular cavity structure 28.1, 28.2, and optionally a further channel 61.2 can lead from the surface 62.1 into the particular cavity structure 28. With respect to the normal direction 24, the central axes of the channel 61.1 and of the channel 61.2 can be congruent or mutually spaced. The right cavity structure 28.1 additionally has a channel 61.3 running within the substrate 14. The middle cavity structure 28.3 has only one channel 61.1 leading from the surface 62.1 into the cavity structure 28.3.

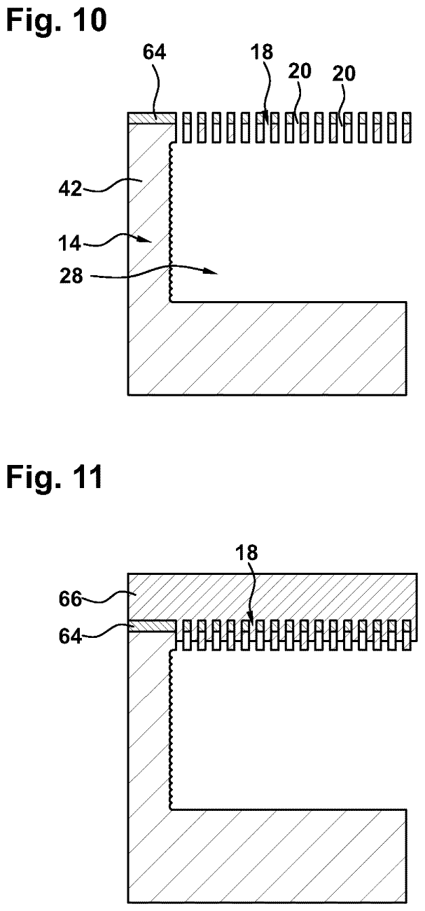

FIG. 10 shows a layer structure of the substrate with monocrystalline silicon as substrate material 42 and a polycrystalline layer 64 of silicon deposited on the monocrystalline silicon of the substrate 14. The formation of the cavity structure 28 takes place here with the aid of a lattice structure 18 in which the trench structures 20 for forming the lattice structure 18 extend through the polycrystalline silicon layer 64 into the monocrystalline silicon substrate 14.

In FIG. 11, the layer structure of the substrate from FIG. 10 is supplemented by growing further polycrystalline silicon 66 on the polycrystalline layer 64. By growing further polycrystalline silicon 66, the lattice structure 18 can also be closed in a gas-tight manner.

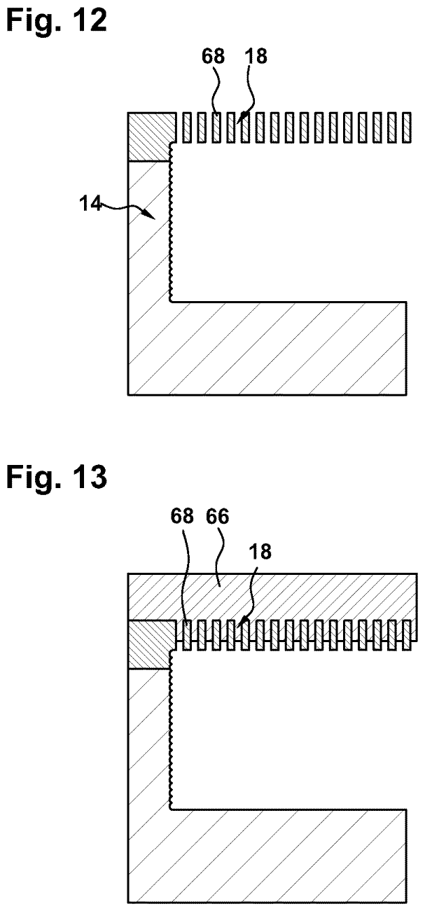

In FIG. 12, the lattice structure 18, in contrast to the layer structure of FIG. 10, consists entirely of a polycrystalline layer 68 of silicon applied to the substrate 14.

FIG. 13 shows the layer structure of the substrate from FIG. 12 after the growth of further polycrystalline silicon 66 in and on the lattice structure 18. By growing additional polycrystalline silicon 68, the lattice structure 18 can also be closed in a gas-tight manner.

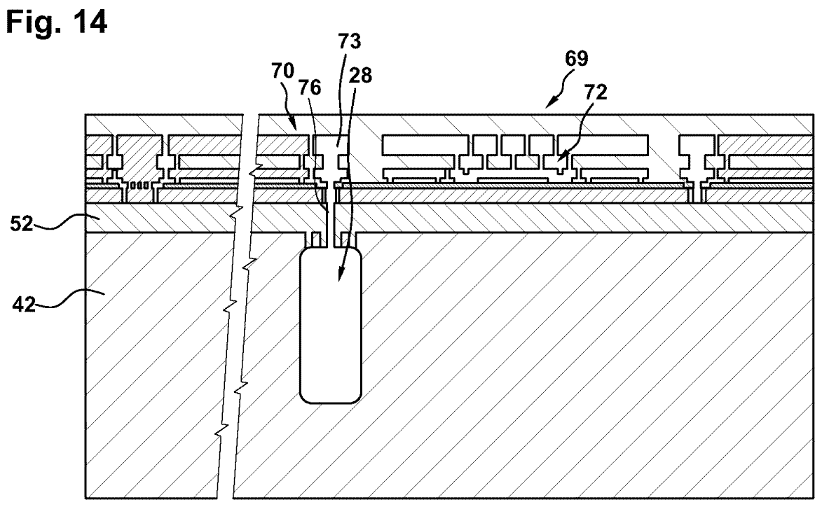

FIG. 14 to 18 each show a cross section of a micromechanical sensor in a specific embodiment of the present invention. FIG. 14 shows a micromechanical sensor 69, which has a layer system 70 on a top layer 52 on the substrate material 42 and a cavity structure 28 in the substrate material 42. The layer system 70 may include or contain ASIC and/or MEMS components. The micromechanical sensor 69 can be a pressure sensor and the layer system 70 can, for example, have or form a capacitive measuring element 72 for pressure measurement. A cavity 73 provided in the capacitive measuring element 72 is further connected fluidically via a first channel 76 to the cavern structure 28 in the substrate material 42.

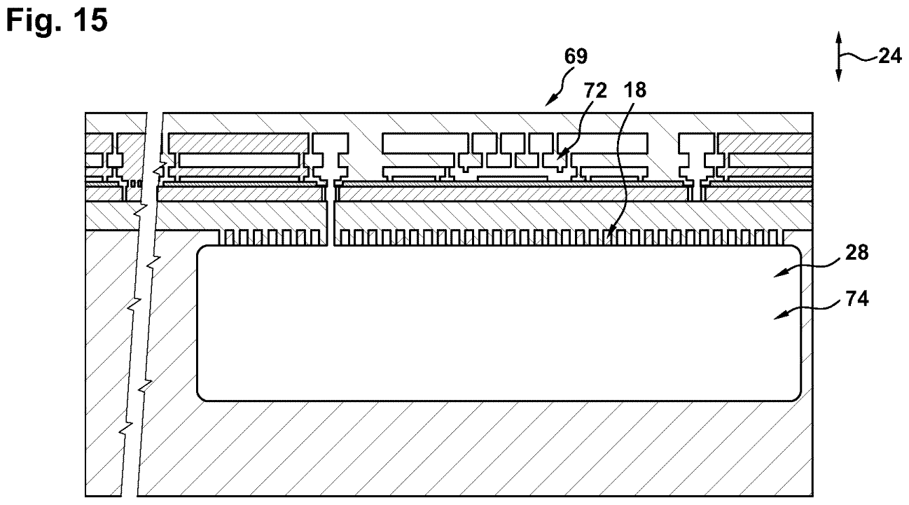

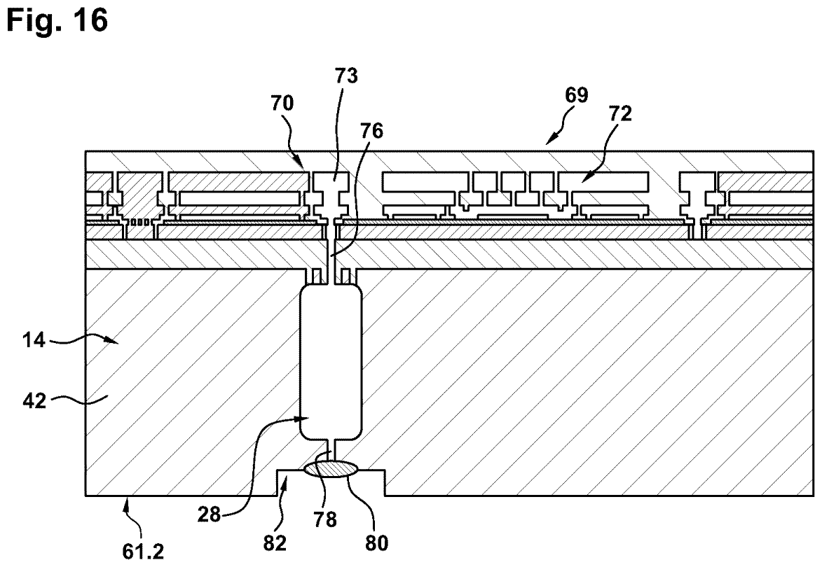

FIG. 15 shows a micromechanical sensor 69 as shown in FIG. 14, but the lattice structure 18 and the cavity structure 28 are wider with respect to a plane having the normal direction 24. The cavity structure 28 forms a hollow space 74 which can extend at least partially below the capacitive measuring element 72 and/or below a region surrounding the capacitive measuring element 72.

FIG. 16 shows a micromechanical sensor 69 as in FIG. 14, but the cavity structure 28 is connected to a first channel 76 and to a second channel 78 opposite. The first channel 76 leads into the cavity 73 provided in the capacitive measuring element 72 and, by means of the layer system 70 on the substrate material 42, is media-tight with respect to an environment surrounding the micromechanical sensor 69. The second channel 78 extends from the surface 61.2 of the substrate 14 opposite the layer system 70 into the cavity structure 28 and is closed at the surface 61.2 by a closure material 80. The second channel 78 can be formed in the region of a surface depression 82 in the substrate 14. The second channel 78 can be closed by melting silicon, for example by melting the substrate material 42 made of silicon with a laser and/or by depositing at least one material layer.

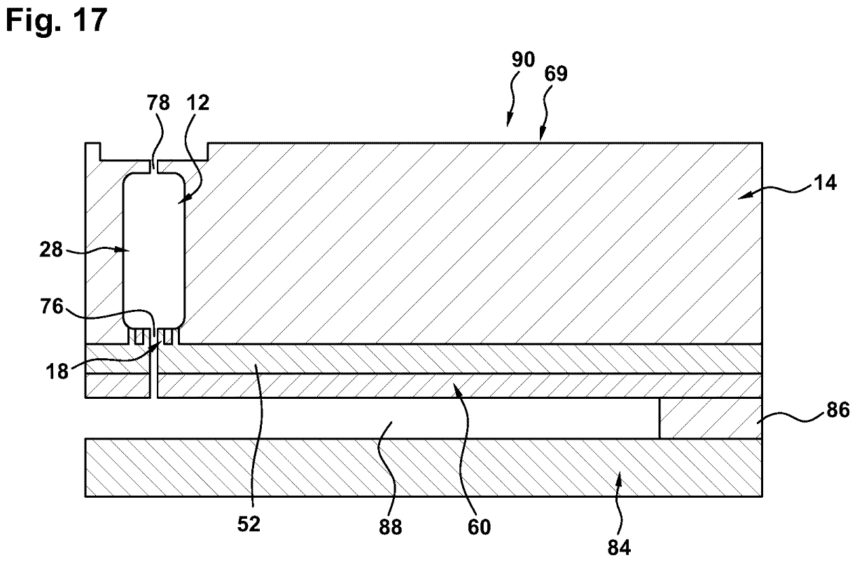

FIG. 17 shows a micromechanical sensor 69 with a substrate 14, with a hollow structure 12, with a lattice structure 18 closed in a gas-tight manner, and a cavity structure 28 adjacent to the lattice structure 18 within the substrate 14, into which cavity structure a first channel 76 and a second channel 78 opposite the first channel 76 lead. The substrate 14 has a layer structure 60 on the top layer 52 covering the lattice structure 18, which layer structure is connected to a further substrate 84, for example by a bond connection 86. An intermediate space 88, which is predefined by the bond connection 86, is formed between the layer structure 60 and the further substrate 84.

The cavity structure 28 with the first channel 76 and the second channel 78 can connect the intermediate space 88 to a surface 90 of the micromechanical sensor 69. This allows, for example, pressure access between the surface 90 and the intermediate space 88 to be implemented through the hollow structure 12. As a result, for example, a pressure sensor arranged in the intermediate space 88 or adjacent to the intermediate space 88 can measure an ambient pressure present at least in the region of the first channel 76 on the surface 90 and/or a change in the ambient pressure of the environment. The hollow structure 12 having the cavity structure 28, the first channel 76 and the second channel 78 can form a fluid passage for supplying the intermediate space 88 with a fluid.

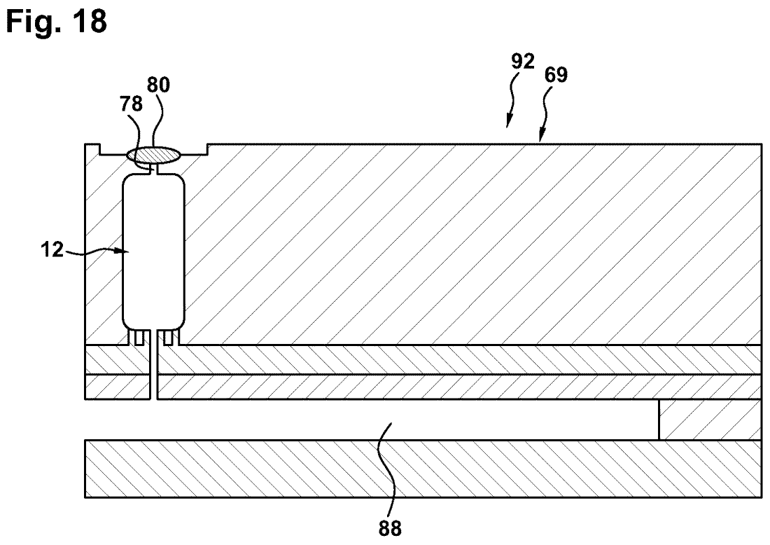

FIG. 18 shows a micromechanical sensor 69 as in FIG. 17, but the second channel 78 is closed by a closure material 80. The closure material 80 can seal off the hollow structure 12 and the intermediate space 88 from an environment 92 in a gas-tight manner.

What is claimed is:

1. A method for making a hollow structure in a substrate, comprising the following steps:
creating a lattice structure with at least two mutually spaced trench structures;
creating a cavity structure below the lattice structure with respect to a normal direction by forming a buried, contiguous cavity that spans at least an area of the two trench structures;
wherein the cavity structure is extended below and directly adjacent to the cavity with respect to the normal direction in the substrate by forming a buried, contiguous further cavity that spans at least the area of the two trench structures by carrying out a cavity formation method including:
applying a passivation layer at least to surfaces of the cavity,
removing the passivation layer exclusively on a bottom surface of the cavity with respect to the normal direction, and
performing an etching process for removing the substrate material of the substrate below the bottom surface by supplying an etching substance through the lattice structure.

2. The method according to claim 1, wherein the cavity and/or the further cavity has a surface area spanning at least the entire lattice structure with respect to a plane having the normal direction as a normal.

3. The method according to claim 1, wherein the cavity formation method is applied at least once more starting from the further cavity.

4. The method according to claim 1, wherein at least two passivation layers that are applied during creation of the cavity and the formation of the further cavity and/or at least one additional further cavity when the cavity formation method is carried out again, are constructed or formed from different materials from one another.

5. The method according to claim 1, wherein after the cavity formation method has been carried out, the lattice structure is formed in a layer structure that spans the cavity structure in a self-supporting manner.

6. The method according to claim 1, after the cavity has been formed using the cavity formation method, the passivation layer is also applied to an underside of a side of the lattice structure facing the cavity.

7. The method according to claim 1, wherein the substrate is constructed from silicon.

8. The method according to claim 1, wherein after the creation of the cavity structure, a depth of the cavity structure along the normal direction is greater than at least a width and/or length of the cavity structure in a direction perpendicular thereto.

9. The method according to claim 1, wherein, after the creation of the cavity structure, at least one channel connected to the cavity structure is formed.

10. The method according to claim 1, wherein, after the creation of the cavity structure, a top layer, which covers at least the lattice structure, is applied.

11. The method according to claim 1, wherein the lattice structure is closed after the creation of the cavity structure.

12. A micromechanical sensor, comprising:
a layer system; and
a hollow structure arranged below the layer system, the hollow structure being formed by:
creating a lattice structure with at least two mutually spaced trench structures,
creating a cavity structure below the lattice structure with respect to a normal direction by forming a buried, contiguous cavity that spans at least an area of the two trench structures,
wherein the cavity structure is extended below and directly adjacent to the cavity with respect to the normal direction in a substrate by forming a buried, contiguous further cavity that spans at least the area of the two trench structures by carrying out a cavity formation method including:
applying a passivation layer at least to surfaces of the cavity,
removing the passivation layer exclusively on a bottom surface of the cavity with respect to the normal direction, and
performing an etching process for removing the substrate material of the substrate below the bottom surface by supplying an etching substance through the lattice structure.
